(19) United States
(12) Patent Application Publication
(10) Pub. No.: US 2006/0138488 A1
(43) Pub. Date: Jun. 29, 2006

(54) Image sensor test patterns for evaluating light-accumulating characteristics of image sensors and methods of testing same

(76) Inventor: Young-chan Kim, Gyeonggi-do (KR)

Correspondence Address: MYERS BIGEL SIBLEY & SAJOVEC, PO BOX 37428, RALEIGH, NC, 27627, US

(21) Appl. No.: 11/315,471

(22) Filed: Dec. 22, 2005

(30) Foreign Application Priority Data
Dec. 29, 2004 (KR) 2004-115046

(51) Int. Cl. H01L 31/113

(52) U.S. Cl. 257/292

(57) ABSTRACT

An image sensor test pattern provides time efficient optical testing of CMOS image senors at a single luminous intensity. These test patterns include at least first and second arrays of pixels having different light-accumulating characteristics. The different light-accumulating characteristics may be achieved multiple different ways. In some cases, the photodiodes in the first array of pixels are larger than photodiodes in the second array of pixels. In other cases, the photodiodes in the first array of pixels have open holes of a first size and the photodiodes in the second array of pixels have open holes of a second size less than the first size. In still other cases, the photodiodes in the first array of pixels have colors filters of a first density (or first thickness) and the photodiodes in the second array of pixels have color filters of a second density (or second thickness) less than the first density (or first thickness).

### REFERENCE TO PRIORITY APPLICATION

This application claims priority to Korean Patent Application No. 2004-115046, filed Dec. 29, 2004, the disclosure of which is hereby incorporated herein by reference.

### FIELD OF THE INVENTION

The present invention relates to image sensors and methods of testing image sensors.

### BACKGROUND OF THE INVENTION

An image sensor is a semiconductor device for converting optical images into electric signals. Charge coupled devices (CCDs) and CMOS image sensors are examples of image sensors. The CCD is a device in which MOS capacitors are located adjacent to each other, and charge carriers are stored on each capacitor. The CMOS image sensor is a switch type device which uses a control circuit and a signal processing circuit as a peripheral circuit, with as many MOS transistors as the number of pixels, and sequentially detects outputs from the capacitors using the MOS transistors. The CCD has the disadvantages of a relatively complex driving scheme, high power consumption, and a complex manufacturing process requiring a number of mask steps. Further, since the CCD cannot have a built-in signal processing circuit, it is difficult to realize the signal processing circuit in one chip.

The CMOS image sensor has recently been developed by using sub-micron CMOS manufacturing technology to overcome such disadvantages. The CMOS image sensor realizes images by forming a photo diode and a MOS transistor within a unit pixel and sequentially detecting signals with a switch scheme. The CMOS image sensor has low power consumption, due to the CMOS manufacturing technology, which is simple compared to the CCD process. Further, the CMOS image sensor can combine a plurality of signal processing circuits in one chip, placing it in the spotlight as a next-generation image sensor. The realization of images in the CMOS image sensor is dependent on the number of electrons generated in a photodiode, according to the number of photons of incident light. Therefore, it is important to test the characteristics of the image sensor according to the number of photons of incident light, before image sensor products are brought to the market. The characteristics of the image sensor according to the number of photons is represented by sensitivity, quantum efficiency, conversion gain, signal to noise ratio, photon shot noise, etc. To observe such characteristics, the luminous intensity of a light source is varied to adjust the number of incident photons, while monitoring the characteristics of the image sensor. However, this process is time consuming, which increases the production cost.

### SUMMARY OF THE INVENTION

The present invention provides a test pattern of optical characteristics of a CMOS image sensor capable of reducing the time required for testing the CMOS image sensor.

The present invention also provides a test method of optical characteristics of a CMOS image sensor-capable of reducing the time required for testing the CMOS image sensor.

According to an aspect of the present invention, there is provided a test pattern of optical characteristics of a CMOS image sensor, the test pattern including a pixel array region having optically blocked photodiodes, a pixel array region including photodiodes of a normal size, and a plurality of pixel array regions including photodiodes of sizes proportional to the normal size.

According to another aspect of the present invention, there is provided a test pattern of optical characteristics of a CMOS image sensor, the test pattern including a pixel array region having optically blocked photodiodes, a pixel array region including photodiodes having an open hole of a normal size, and a plurality of pixel array regions including photodiodes having open holes of a size proportional to the normal size.

According to another aspect of the present invention, there is provided a test pattern of optical characteristics of a CMOS image sensor, the test pattern including a pixel array region having optically blocked photodiodes, a pixel array region including photodiodes having a color filter of a normal thickness or density, and a plurality of pixel array regions including photodiodes having color filters of a thickness or density proportional to the normal thickness or density.

According to another aspect of the present invention, there is provided a test method of optical characteristics of a CMOS image sensor, the test method including setting a test pattern region for monitoring optical characteristics, in a CMOS image sensor chip, locating a pixel array including photodiodes of a normal size, in the test pattern region, locating a plurality of pixel array regions including photodiodes of sizes proportional to the normal size, in the test pattern region, and testing the optical characteristics of the CMOS image sensor at a single luminous intensity using the pixel arrays within the test pattern region.

According to another aspect of the present invention, there is provided a test method of optical characteristics of a CMOS image sensor, the test method including setting a test pattern region for monitoring the optical characteristics, in a CMOS image sensor chip, locating a pixel array including photodiodes having an open hole of a normal size, in the test pattern region, locating a plurality of pixel array regions including photodiodes having open holes of sizes proportional to the normal size, in the test pattern region, and testing the optical characteristics of the CMOS image sensor at a single luminous intensity using the pixel arrays within the test pattern region.

According to another aspect of the present invention, there is provided a test method of optical characteristics of a CMOS image sensor, the test method including setting a test pattern region for monitoring the optical characteristics, in a CMOS image sensor chip, locating a pixel array including photodiodes having a color filter of a normal thickness or a normal density, in the test pattern region, locating a plurality of pixel array regions including photodiodes having color filters of a thickness or a density proportional to the normal thickness or the normal density, in the test pattern region, and testing the optical characteristics of the CMOS image sensor at a single luminous intensity using the pixel arrays within the test pattern region.

### BRIEF DESCRIPTION OF THE DRAWINGS

FIG. 1 is a diagram illustrating a test pattern of optical characteristics of a CMOS image sensor according to a first embodiment of the present invention;

FIG. 2 is a circuit diagram illustrating a circuit of a unit pixel in pixel array regions shown in FIG. 1;

FIG. 3 is a diagram illustrating the layout of the unit pixel;

FIG. 4 is a diagram illustrating a test pattern of optical characteristics of a CMOS image sensor according to a second embodiment of the present invention;

FIG. 5 is a sectional view taken along line 5-5′ of the layout of the unit pixel shown in FIG. 3; and

FIG. 6 is a diagram illustrating a test pattern of optical characteristics of a CMOS image sensor according to a third embodiment of the present invention.

### DETAILED DESCRIPTION OF THE INVENTION

The attached drawings illustrate exemplary embodiments of the present invention, and are referred to in order to gain a sufficient understanding of the present invention, the merits thereof, and the objectives accomplished by the implementation of the present invention. Like reference numerals denote like elements throughout the drawings.

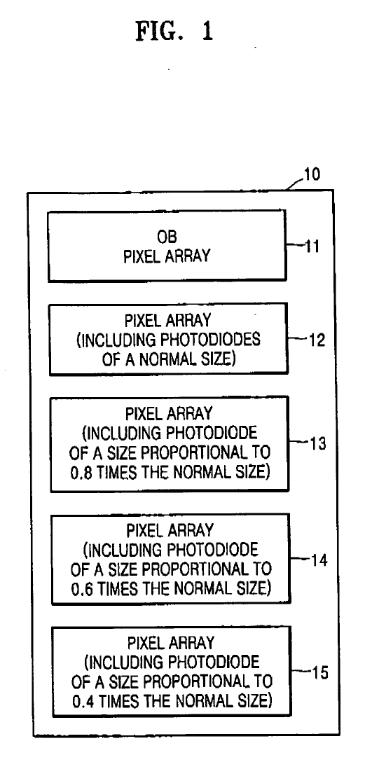

FIG. 1 is a diagram illustrating a test pattern of optical characteristics of a CMOS image sensor according to a first embodiment of the present invention. The test pattern 10 of the optical characteristics according to the first embodiment of the present invention includes a pixel array region 11 including optically blocked photo diodes, a pixel array region 12 including photodiodes of a normal size, and a plurality of pixel array regions 13 to 15 including photodiodes of a size proportional to the normal size. For example, the pixel array regions 13, 14, and 15 may include photodiodes of a size proportional to 0.8 times, 0.6 times, and 0.4 times the normal size, respectively. Here, the normal size means the size of photodiodes used in a typical production scale image sensor chip.

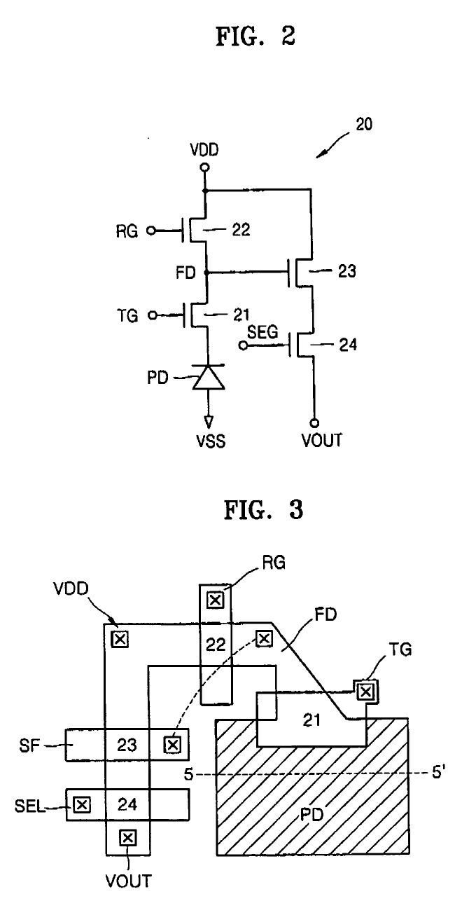

FIG. 2 is a circuit diagram illustrating a circuit of a unit pixel 20 in pixel array regions 11 to 15 shown in FIG. 1, and FIG. 3 is a diagram illustrating the layout of the unit pixel 20. A unit pixel 20 includes a photodiode (PD) which receives photons of light and generates electrons, a transfer transistor 21 which transfers the electrons generated at the photodiode (PD) to a floating diffusion region (FD), a reset transistor 22 which sets the electric potential of the floating diffusion region (FD) to a desired value and resets the floating diffusion region (FD) by emitting electric charge, a drive transistor 23 serving as a source follower buffer amplifier, and a select transistor 24 which performs the function of addressing. A voltage (Vout) is output through the select transistor 24.

As illustrated by FIG. 2, a transfer control signal (TG) is applied to the gate of the transfer transistor 21, and a reset control signal (RG) is applied to the gate of the reset transistor 22. The floating diffusion region (FD) is connected to the gate of the drive transistor 23. A selection control signal (SEG) is applied to the gate of the select transistor 24.

A test method of the optical characteristics of the CMOS image sensor using the test pattern according to the first embodiment will be described in detail. Generally, in the CMOS image sensor, the number of electrons which are photoelectrically converted from photons of incident light is in proportion to the size of the photodiode (PD). Specifically, the number of electrons generated at a specific luminous intensity varies depending on the size of the photodiode (PD).

In the test method using the test pattern of the optical characteristics according to the first embodiment, a test pattern region 10 for monitoring the optical characteristics is set in the CMOS image sensor chip, a pixel array 12 including photodiodes of a normal size, and a plurality of pixel array regions 13 to 15 including photodiodes of a size proportional to the normal size are located in the test pattern region 10, and then the optical characteristics of the CMOS image sensor at a single luminous intensity are tested by using the pixel arrays within the test pattern region.

In the test method using the test pattern of the optical characteristics according to the first embodiment, the optical characteristics of the image sensor are tested by using pixel arrays including photodiodes of different sizes, thus obtaining the same effect as varying the luminous intensity of photodiodes having uniform size. The optical characteristics are tested at a single luminous intensity, instead of a varying luminous intensity, thus reducing the time required for testing the optical characteristics of the image sensor. The optical characteristics of the CMOS image sensor are typically represented by sensitivity, conversion gain, signal to noise ratio, quantum efficiency, photon shot noise, etc.

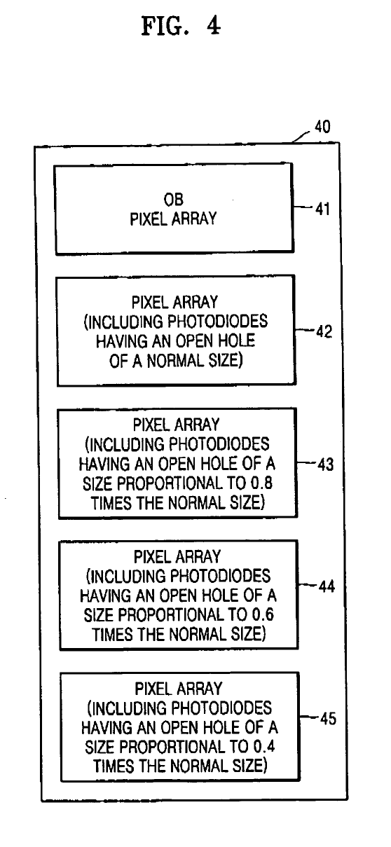

FIG. 4 is a diagram illustrating a test pattern of optical characteristics of a CMOS image sensor according to a second embodiment of the present invention. The test pattern 40 of the optical characteristics according to the second embodiment of the present invention includes a pixel array region 41 including optically blocked photodiodes, a pixel array region 42 including photodiodes having an open hole of normal size, and a plurality of pixel array regions 43 to 45 including photodiodes having open holes of sizes proportional to the normal size. For example, the pixel array regions 43, 44, and 45 may include photodiodes having open holes of a size proportional to 0.8 times, 0.6 times, and 0.4 times the normal size, respectively. Here, the normal size means the size of the open hole of the photodiodes used in a production-scale CMOS image sensor chip.

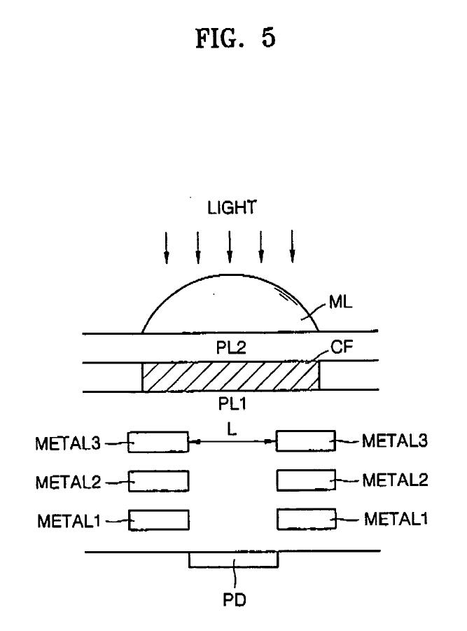

FIG. 5 is a sectional view taken along line 5-5′ of the layout of the unit pixel shown in FIG. 3. Here, METAL1 to METAL3, CF, ML, and PL1 and PL2 represent metal lines, a color filter, a microlens, and planarization layers, respectively. “L” represents the distance between the metal lines, and corresponds to the open hole of the photodiode through which light passes. The first metal line (METAL1) is used for connecting the output voltage (Vout) and the drive transistor 23 to the FD shown FIG. 3. The second metal line (METAL2) is used for routing signals RG, TG, and SEL shown in FIG. 3. The third metal line (METAL3) is used for routing a power source voltage and for an optical shield.

A test method of the optical characteristics of the CMOS image sensor using the test pattern according to the second embodiment will be described in detail. In the CMOS image sensor, the number of electrons which are photoelectrically converted from photons of incident light is in proportion to the size of the photodiode (PD) and the size of the open hole (L) of the photodiode (PD). Specifically, the number of electrons generated at a specific luminous intensity varies depending on the size of the open hole (L) of the photodiode (PD).

In the test method using the test pattern of the optical characteristics according to the second embodiment, a test pattern region 40 for monitoring the optical characteristics is set in the CMOS image sensor chip, a pixel array 42 including photodiodes having an open hole of a normal size and a plurality of pixel array regions 43 to 45 including photodiodes having open holes of a size proportional to the normal size are located in the test pattern region 40, and then the optical characteristics of the CMOS image sensor are tested at a single luminous intensity using the pixel arrays 42 to 45 within the test pattern region.

In the test method using the test pattern of the optical characteristics according to the second embodiment, the optical characteristics of the image sensor are tested by using pixel arrays, each including photodiodes having open holes of different sizes, thus obtaining the same effect as varying the luminous intensity. The optical characteristics are tested at a single luminous intensity instead of a varying luminous intensity, thereby reducing the time required for testing the optical characteristics of the image sensor.

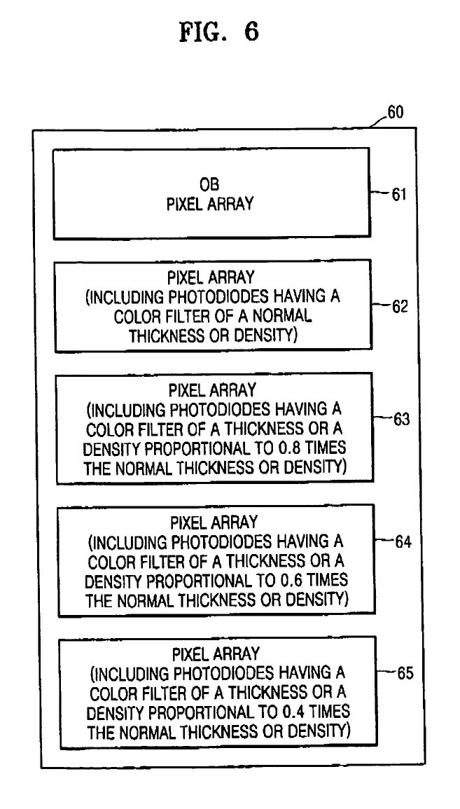

FIG. 6 is a diagram illustrating a test pattern of optical characteristics of a CMOS image sensor according to a third embodiment of the present invention. The test pattern 60 of the optical characteristics according to the third embodiment of the present invention includes a pixel array region 61 including optically blocked photodiodes, a pixel array region 62 including photodiodes having a color filter (CF shown in FIG. 5) of a normal thickness or density, and a plurality of pixel array regions 63 to 65 including photodiodes having color filters of a thickness or density proportional to the normal thickness or density.

For example, the pixel array regions 63, 64, and 65 may include photodiodes having a color filter of a thickness or density proportional to 0.8 times, 0.6 times, and 0.4 times the normal thickness or density, respectively. Here, the normal thickness and the normal density mean the thickness and the density of the color filter actually used in a CMOS image sensor chip.

A test method of the optical characteristics of the CMOS image sensor by using the test pattern according to the third embodiment will be described in detail. In the CMOS image sensor, the number of electrons which are photoelectrically converted from photons of incident light may be controlled according to the thickness and density of the color filter (CF). Specifically, the number of electrons generated at a specific luminous intensity varies depending on the thickness and density of the color filter (CF).

In the test method using the test pattern of the optical characteristics according to the third embodiment, a test pattern region 60 for monitoring the optical characteristics is set in the CMOS image sensor chip, a pixel array 62 including photodiodes having a color filter (CF) of a normal thickness and density and a plurality of pixel array regions 63 to 65 including photodiodes having color filters (CF) of a thickness or density proportional to the normal thickness or the normal density are located in the test pattern region 60, and then the optical characteristics of the CMOS image sensor at a single luminous intensity are tested using the pixel arrays 62 to 65 within the test pattern region.

In the test method using the test pattern of the optical characteristics according to the third embodiment, the optical characteristics of the image sensor are tested by using pixel arrays including photodiodes having color filters of different thickness or density, thus obtaining the same effect as varying the luminous intensity. The optical characteristics are tested at a single luminous intensity instead of a varying luminous intensity, thereby reducing the time required for testing the optical characteristics of the image sensor.

As described above, in a test method using a test pattern of optical characteristics according to the present invention, the optical characteristics are tested at a single luminous intensity, without varying the luminous intensity. Therefore, the optical characteristics of the image sensor can be tested much more quickly.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An image sensor test pattern, comprising:
at least first and second arrays of pixels having different light-accumulating characteristics.

2. The image sensor test pattern of claim 1, wherein photodiodes in the first array of pixels are larger than photodiodes in the second array of pixels.

3. The image sensor test pattern of claim 1, wherein photodiodes in the first array of pixels have open holes of a first size; and wherein photodiodes in the second array of pixels have open holes of a second size less than the first size.

4. The image sensor test pattern of claim 1, wherein photodiodes in the first array of pixels have colors filters of a first density; and wherein photodiodes in the second array of pixels have color filters of a second density less than the first density.

5. The image sensor test pattern of claim 1, wherein photodiodes in the first array of pixels have colors filters of a first thickness; and wherein photodiodes in the second array of pixels have color filters of a second thickness less than the first thickness.

6. The image sensor test pattern of claim 1, further comprising a third array of pixels having optically blocked photodiodes therein.

7. The image sensor test pattern of claim 1, wherein each of the pixels in the first and second arrays of pixels comprises a respective CMOS image sensor.

8. A test pattern of optical characteristics of a CMOS image sensor, the test pattern comprising:
a pixel array region including photodiodes of a normal size; and
a plurality of pixel array regions including photodiodes of sizes proportional to the normal size.

9. The test pattern of the optical characteristics of the CMOS image sensor according to claim 8, further comprising a pixel array region including optically blocked photodiodes.

10. A test pattern of optical characteristics of a CMOS image sensor, the test pattern comprising:
a pixel array region including photodiodes having an open hole of a normal size; and
a plurality of pixel array regions including photodiodes having open holes of a size proportional to the normal size.

11. The test pattern of the optical characteristics of the CMOS image sensor according to claim 10, further comprising a pixel array region including optically blocked photodiodes.

12. A test pattern of optical characteristics of a CMOS image sensor, the test pattern comprising:
a pixel array region including photodiodes having a color filter of a normal thickness or a normal density; and
a plurality of pixel array regions including photodiodes having color filters of a thickness or a density proportional to the normal thickness or the normal density.

13. The test pattern of the optical characteristics of the CMOS image sensor according to claim 12, further comprising a pixel array region including optically blocked photodiodes.

14. A test method of optical characteristics of a CMOS image sensor, the method comprising:
setting a test pattern region for monitoring the optical characteristics, in a CMOS image sensor chip;
locating a pixel array including photodiodes of a normal size, in the test pattern region;
locating a plurality of pixel array regions including photodiodes of sizes proportional to the normal size, in the test pattern region; and
testing the optical characteristics of the CMOS image sensor at a single luminous intensity using the pixel arrays within the test pattern region.

15. The test method of the optical characteristics of the CMOS image sensor according to claim 14, wherein the optical characteristics are sensitivity, conversion gain, signal to noise ratio, quantum efficiency, or photon shot noise.

16. A test method of optical characteristics of a CMOS image sensor, the method comprising:
setting a test pattern region for monitoring the optical characteristics, in a CMOS image sensor chip;
locating a pixel array including photodiodes having an open hole of a normal size, in the test pattern region;
locating a plurality of pixel array regions including photodiodes having open holes of a size proportional to the normal size, in the test pattern region; and
testing the optical characteristics of the CMOS image sensor at a single luminous intensity using the pixel arrays within the test pattern region.

17. The test method of the optical characteristics of the CMOS image sensor according to claim 16, wherein the optical characteristics are sensitivity, conversion gain, signal to noise ratio, quantum efficiency, or photon shot noise.

18. A test method of optical characteristics of a CMOS image sensor, the method comprising:
setting a test pattern region for monitoring the optical characteristics, in a CMOS image sensor chip;
locating a pixel array including photodiodes having a color filter of a normal thickness or a normal density, in the test pattern region;
locating a plurality of pixel array regions including photodiodes having color filters of a thickness or a density proportional to the normal thickness or the normal density, in the test pattern region; and
testing the optical characteristics of the CMOS image sensor at a single luminous intensity using the pixel arrays within the test pattern region.

19. The test method of the optical characteristics of the CMOS image sensor according to claim 18, wherein the optical characteristics are sensitivity, conversion gain, signal to noise ratio, quantum efficiency, or photon shot noise.
